(19) United States
(12) Patent Application Publication
(10) Pub. No.: US 2014/0263979 A1
(43) Pub. Date: Sep. 18, 2014

(54) PHOTOCONDUCTIVE SWITCH WITH IMPROVED LIFE SPAN

(71) Applicant: LAWRENCE LIVERMORE NATIONAL SECURITY, LLC, Livermore, CA (US)

(72) Inventor: Gary Guethlein, Livermore, CA (US)

(73) Assignee: LAWRENCE LIVERMORE NATIONAL SECURITY, LLC, Livermore, CA (US)

(21) Appl. No.: 13/830,741

(22) Filed: Mar. 14, 2013

(51) Int. Cl. H01L 31/09; H01L 31/16; H01L 31/0312

(52) U.S. Cl. CPC H01L 31/09; H01L 31/0312; H01L 31/162
USPC 250/214 SW; 257/77; 257/432

(57) ABSTRACT

Methods, devices and systems enhance the operation and lifespan of photoconductive switches. A photoconductive switch is described that includes a photoconductive material with a first face and a second face, as well as a first contact and a second contact that are positioned above a top surface and below a bottom surface of the photoconductive material, respectively. The first and the second contacts enable establishment of an electric field across the photoconductive material, where the electric field includes enhancement regions around the periphery of the first and second contacts. Further, the photoconductive material is dimensioned relative to the first and the second contacts, as well as first radiation extent and divergence, to allow a first incident radiation that enters the photoconductive material through the first face to propagate through the photoconductive material toward the second face and reach one or more regions of electric field enhancement with substantially reduced intensity.

### FEDERALLY SPONSORED RESEARCH OR DEVELOPMENT

The United States Government has rights in this invention pursuant to Contract No. DE-AC52-07NA27344 between the United States Department of Energy and Lawrence Livermore National Security, LLC for the operation of Lawrence Livermore National Laboratory.

### TECHNICAL FIELD

The present application generally relates to photoconductive switches and methods for enhancing the operation of photoconductive switches.

### BACKGROUND

A photoconductive switch is an electrical switch that operates based on an increase in its electrical conductance when the semiconductor switch material is irradiated with light. In the absence of light, the switch is in its “off” state since there are insufficient free carriers within the semiconductor material to allow appreciable current flow in the switch. When the properly biased semiconductor is irradiated with light of sufficient energy and fluence, photons with energies above the bandgap energy of the properly biased semiconductor material generate free carriers, resulting in a current flow that turn the switch into an “on” state.

Photoconductive switches have applications in many areas including high voltage analog waveform generators, vehicle ignition systems, linear accelerators, radiation therapy systems, RF generators, and the like. In these and other applications, the voltage values maintained across a photoconductive switch must typically remain below a threshold value to prevent breakdown of the semiconductor material and to prolong the life span of the switch.

### SUMMARY

The disclosed embodiments relate to methods, devices and systems that enhance the operation and life span of photoconductive switches. One aspect of the disclosed embodiments relates to a photoconductive switch that includes a photoconductive material structured to comprise a first face and a second face, a first contact and a second contact positioned at two opposing surfaces of the photoconductive material. The first and the second contacts enable establishment of an electric field across the photoconductive material, where the electric field includes enhancement regions around the periphery of the first and the second contacts. Further, the photoconductive material is dimensioned relative to the first and the second contacts to allow a first incident radiation that enters the photoconductive material through the first face to propagate through the photoconductive material toward the second face and reach one or more regions of electric field enhancement with substantially reduced intensity.

In one exemplary embodiment, the photoconductive material is dimensioned relative to the first and the second contacts to allow a second incident radiation that enters the photoconductive material through the second face to propagate through the photoconductive material toward the first face and reach one or more additional regions of electric field enhancement with substantially reduced intensity. According to one exemplary embodiment, the photoconductive material comprises silicon carbide (SiC). In another exemplary embodiment, the first incident radiation is light produced by a laser.

Another exemplary embodiment relates to a system that includes the above noted photoconductive switch. Such a system further includes a first source configured to produce the first incident radiation, where a spatial extent and divergence of the first incident radiation produced by the first source is selected to sustainably avoid illumination of one or more further regions of electric field enhancement, or to allow the first incident radiation that enters the photoconductive material through the first face to propagate through the photoconductive material toward the second face and reach the one or more further regions of electric field enhancement with substantially reduced intensity.

In one exemplary embodiment, the above noted system additionally includes a fiber optic bundle configured to deliver the first incident radiation to the first face of the photoconductive material. In another exemplary embodiment, the system also includes one or more optical components configured to deliver the first incident radiation to the first face of the photoconductive material. For example, the one or more optical components comprise one or more of: a lens, a prism, and a grating. In yet another exemplary embodiment, the system further comprises a voltage source configured to supply one or more voltage values to the first and the second contacts.

In still another exemplary embodiment, in addition to the first source, the system also includes a second source that is configured to produce the second incident radiation. In such an embodiment, a spatial extent and divergence of the second incident radiation produced by the second source is selected to sustainably avoid illumination of the one or more further regions of electric field enhancement, or to allow the second incident radiation that enters the photoconductive material through the second face to propagate through the photoconductive material toward the first face and reach the one or more further regions of electric field enhancement with substantially reduced intensity. In one exemplary embodiment, a single source may be used to operate as the first source and the second source, by, for example, splitting the radiation produced by the single source into two different paths.

According to one exemplary embodiment, the photoconductive switch is configured to operate with a Blumlein of a dielectric wall accelerator. In another exemplary embodiment, the photoconductive material is dimensioned to allow a central region of the photoconductive material be substantially uniformly illuminated by radiation entering the photoconductive material from the first face or radiation entering the photoconductive material from the second face. In yet another exemplary embodiment, the photoconductive material is dimensioned based on at least one of: (a) a length of the photoconductive material relative to a length of the first and the second contacts along a direction of radiation propagation through the photoconductive material, (b) a length of the photoconductive material and a length of the first and the second contacts relative to an amount of radiation absorption along a direction of radiation propagation through the photoconductive material, (c) a width of the photoconductive material, transverse to a direction of radiation propagation through the photoconductive material, relative to a width of a section of the first face or the second face that receives incident radiation, (d) a width of the first and the second contacts, transverse to a direction of radiation propagation through the photoconductive material, relative to a width of a section of the first face or the second face that receives incident radiation, (e) a divergence angle or angles of radiation that enters the photoconductive material through the first face or the second face and propagates through the photoconductive material towards an opposite face, (f) a composition of the photoconductive material, (g) a spacing between individual fibers of a fiber optic bundle configured to deliver the first radiation to the first face of the photoconductive material, or (h) a spacing between individual fibers of a fiber optic bundle configured to deliver a second radiation to the second face of the photoconductive material.

Another aspect of the disclosed embodiments relates to a method for operating a photoconductive switch that includes supplying a voltage value to the photoconductive switch, and delivering a first incident radiation to only a section of a first face of a photoconductive material of the photoconductive switch. The photoconductive material includes the first face and a second face, and the photoconductive material is positioned between a first and a second contact configured to enable establishment of an electric field across the photoconductive material, where the electric field includes enhancement regions around the periphery of the first and the second contacts. Further, the photoconductive material is dimensioned relative to the first and the second contacts such that upon delivering the first incident radiation, the first incident radiation propagates through the photoconductive material toward the second face and reaches one or more regions of electric field enhancement with substantially reduced intensity.

In one exemplary embodiment, a second incident radiation is also delivered to only a section of the second face, where the photoconductive material is dimensioned relative to the first and the second contacts such that upon delivering the second incident radiation, the second incident radiation propagates through the photoconductive material toward the first face and reaches one or more additional regions of electric field enhancement with substantially reduced intensity. According to one exemplary embodiment, the first incident radiation is light produced by a laser. In another exemplary embodiment, delivering the radiation includes delivering the first incident radiation to the first face using a fiber optic bundle. In still another exemplary embodiment, the first incident radiation is delivered to the first face using one or more optical components. For example, the one or more optical components comprise one or more of: a lens, a prism, and a grating. In another exemplary embodiment, upon delivery of the first incident radiation, a current flow is established between the first and the second contacts. Another exemplary embodiment includes substantially eliminating a current flow between the two contacts by reducing or halting one or both of: supply of the voltage to the photoconductive switch, and delivery of the first incident radiation.

According to one exemplary embodiment, delivery of the first incident radiation includes controlling a spatial extent and divergence angle of the first incident radiation such that illumination of one or more further regions of electric field enhancement is avoided, or such that the first incident radiation that enters the photoconductive material through the first face propagates through the photoconductive material toward the second face and reaches the one or more further regions of electric field enhancement with substantially reduced intensity. Another exemplary embodiment that involves delivering a second incident radiation, delivery of the second incident radiation comprises controlling a spatial extent and divergence angle of the second incident radiation such that illumination of one or more further regions of electric field enhancement is avoided, or such that the second incident radiation that enters the photoconductive material through the second face propagates through the photoconductive material toward the first face and reaches the one or more further regions of electric field enhancement with substantially reduced intensity.

### BRIEF DESCRIPTION OF THE DRAWINGS

FIG. 1 illustrates an exemplary linear accelerator within which photoconductive switches of the present application may be utilized.

FIG. 2(a) illustrates a plan view of a photoconductive switch that is used in existing systems.

FIG. 2(b) illustrates a side view of the photoconductive switch of FIG. 2(a).

FIG. 2(c) is a modified diagram of FIG. 2(a) that illustrates the regions of electric field enhancement.

FIG. 2(d) illustrates a side view of the photoconductive switch of FIG. 2(c).

FIG. 2(e) is diagram that illustrates electric field lines between the lower contact pad and the upper contact pad of a photoconductive switch.

FIG. 2(f) is a contour plot illustrating a region of electric field enhancement around an edge of a contact pad.

FIG. 3(a) illustrates a plan view of a photoconductive switch in accordance with an exemplary embodiment.

FIG. 3(b) illustrates a side view of the photoconductive switch of FIG. 3(a).

FIG. 4 illustrates a plan view of a photoconductive switch in accordance with another exemplary embodiment.

FIG. 5 is a set of operations that can be carried out for operating a photoconductive switch in accordance with an exemplary embodiment.

### DETAILED DESCRIPTION

As noted earlier, many applications require operation of photoconductive switches under high voltages. In addition to having to withstand high voltage values, photoconductive switches are often required to be turned on and off at rapid rates, thereby exacerbating the breakdown of photoconductive switch material operating in high voltage environments. For example, in one application related to a linear accelerator system, it is observed that a 1-mm thick Silicon Carbide (SiC) photoconductive switch generally fails below an operating voltage value of 20 KV.

The disclosed embodiments relate to methods, systems and devices for extending the life span of a photoconductive switch and improving the photoconductive switch performance.

FIG. 1 illustrates a simplified diagram of an exemplary linear particle accelerator (linac) 100 that can utilize photoconductive switches of the disclosed embodiments. For simplicity, FIG. 1 only depicts some of the components of the linac 100. Therefore, it is understood that the linac 100 can include additional components that are not specifically shown in FIG. 1. An ion source 102 produces a proton beam that is coupled to a radio frequency quadrupole (RFQ) 106 using coupling components 104. The RFQ 106 provides focusing, bunching and acceleration for the proton beam. One exemplary configuration of a radio frequency quadrupole includes an arrangement of four triangular-shaped vanes that form a small hole, through which the proton beam passes. The edges of the vanes at the central hole include ripples that provide acceleration and shaping of the beam. The vanes are RF excited to accelerate and shape the ion beam passing therethrough. The beam output by RFQ 106 is coupled to a dielectric wall accelerator (DWA) 108 that provides accelerating electric field along the longitudinal direction of the DWA 108 which further accelerates protons in the proton beam to produce the output charged particle beam 110. FIG. 1 also shows Blumlein devices 112a and the associated laser 114 that are used to deliver voltage pulses to the DWA 108 by photoconductive switches 112b, e.g., using light from the laser 114 to trigger the photoconductive switches 112b for controlling the DWA 108. In some example embodiments, a fiber optic array (not shown) can be used to deliver light from the laser 114 to the photoconductive switches 112b. In some embodiments, additionally or alternatively, optical elements such as lenses, prisms, gratings, non-fiber waveguides and the like can be used to facilitate delivery of light from the laser 114 to the photoconductive switches 112b. The timing and control components 116 in FIG. 1 provide the necessary timing and control signals to various components of the linac 100 to ensure proper operation and synchronization of those components.

FIG. 2(a) illustrates a simplified plan view of a photoconductive switch 202 that is used in existing systems. The switch 202 of FIG. 2(a) includes a photoconductive material 204 (e.g., SiC) and two contact pads 206 for connection to a Blumlein and/or voltage source (only one contact is visible in FIG. 2(a)). Light can illuminate the photoconductive switch 202 from one or more sides. In the exemplary diagram of FIG. 2(a) two fiber optic arrays 208, 210 are used to illuminate the photoconductive switch 202 from the left and the right hand sides, respectively. In a typical configuration of existing systems, the photoconductive switch 202 is illuminated uniformly. That is, as illustrated in FIG. 2(a), the light is delivered to substantially all sections of the photoconductive material 204. FIG. 2(b) shows a side view of the exemplary photoconductive switch 202 of FIG. 2(a). In a typical configuration, the diameter of individual fibers are typically less than half of the thickness of the photoconductive material 204. In FIG. 2(b) the path of incident light from the left hand side is shown by dashed lines and the path of incident light from the right hand side is shown by solid lines. As shown in FIG. 2(b), in such a configuration, the light from the right hand side reaches the left hand side and the light from the left hand side reaches the right hand side of the switch 204.

It has been observed that SiC photoconductive switches that are subject to high voltages and substantially uniform light have a short light span. For example, such a switch may only last for 10 shots (i.e., 10 on-off cycles) when operating above a voltage of 20 KV. The failure to operate is, at least in-part, due to electric field enhancements that are known to exist at the edges of contact locations with the photoconductive material. FIG. 2(c) is a simplified diagram that illustrates the regions 216(a) through 216(d) (cross-hatched regions) of electric field enhancement. FIG. 2(d) is a cross-sectional view of FIG. 2(c), in which the regions 216(a) and 216(c) of electric field enhancements are shown for the upper and lower contact pads 206. In FIG. 2(d), the electric field enhancement for regions 216(b) and 216(d) are not shown, as FIG. 2(d) provides across-sectional view around the middle of the switch 202. The enhancement fields occur around the perimeter of contact pads 206 with photoconductive material 204 and subsequent current enhancements cause physical damage to the photoconductive material at high operating voltage.

Due to field enhancements, a uniform incident light does not produce a uniform current density in the photoconductive material. Thus if, for example, there is a 10× field enhancement around the contact edges compared to the bulk material away from edge locations, then the same volume of photoconductive material that is subject to field enhancements carries 10× current density compared to the current density of bulk material. FIG. 2(e) is simplified diagram that illustrates electric field lines 218 between the lower contact pad 206(b) and the upper contact pad 206(a). Field enhancements occur where the fringing fields converge on the edge of each contact. For uniform illumination, and hence uniform conductivity, the current paths will follow the electric field lines 218 and also converge along the edge of the contacts. In this case, the current is enhanced in the same manner and ratio as the electric field.

Reducing field enhancements at edge locations is not a trivial task and can require modifications to the shape and other characteristics of the switch, which may not be practically and economically feasible. Moreover, it is unlikely that field enhancements can be eliminated altogether. FIG. 2(f) shows simulation results corresponding to the electric field around an edge of the contact pad 206(a). The contour plot in FIG. 2(f) shows an area of electric field enhancement 220 that persists even when the contact pad 206(a) is modified to include rounded corners.

According to the disclosed embodiments, the amount of physical damage to the photoconductive material is reduced or substantially eliminated by limiting the exposure of edge locations to incident light. That is, despite the presence of field enhancement regions, physical damage to the photoconductive material that are subject to field enhancements is reduced by eliminating, or substantially reducing, the exposure of those regions to incident light. Therefore, the disclosed embodiments, at least in-part, control the spatial distribution of the illumination, and thus the conductivity of the photoconductive material so that less current is collected at the field enhancement points.

FIG. 3(a) is a simplified plan view of a photoconductive switch 302 in accordance with an exemplary embodiment. In the exemplary diagram of FIG. 3(a), the photoconductive switch 302 includes photoconductive material 304 and contact pads 306, and is illuminated by two fiber optic arrays 308, 310 from two directions. In FIG. 3(a), exposure of edge regions to incident light is reduced at least by reducing the vertical extent (e.g., X-direction as depicted in FIG. 3(a)) on the fiber delivery system relative to the dimension of the contact pads 306 in X-direction. As such, the incident light is primarily incident on the center portion of photoconductive switch 306 along the edge 316(a), thus direct illumination of locations along the edges 316(b) and 316(d), which are subject to field enhancements, is avoided. In the specific example in FIG. 3(a), optical fibers are positioned relative to the photoconductive material to direct light into the photoconductive material at locations towards the center portion of photoconductive material while being away from one or more electric field enhancement regions around the periphery of the contacts 306. One fiber bundle may be adequate to deliver sufficient optical power to cause the photoconductive material to become photoconductive to provide electrical conductivity in the photoconductive material between the contacts. In the example illustrated, two fiber bundles 308 and 310 are used to direct two optical beam bundles into the two opposite faces of the photoconductive material to trigger the photoconductivity.

To illustrate this concept, let's examine the light that is delivered by fiber optic bundle 308 to the center section of the first face 312 of the photoconductive switch 302 under a desired scenario. By illuminating only the center section of the first face 312, current at the field enhancements, and thus physical damage, along the edges 316(b) and 316(d) of the photoconductive switch 302 are eliminated, or reduced. The rays of light (i.e., dashed lines) that enter the photoconductive material 304 through the first face 312 expand as they propagate through the photoconductive material 304 in the direction of the second face 314. While the expanded light may ultimately reach field enhancement regions on the right hand side of the photoconductive switch 302 along the edge 316(b), the expanded light is also attenuated as it propagates through the photoconductive material 304. By selecting the proper dimensions, including the length, L, and width, W, of the photoconductive material 304, the length LL and width WW of the contact pad 306, and the extent, D, of fiber bundle 308 in X-direction relative to width WW, the intensity of the light that reaches edges 316(b) and 316(d), as well the light that reaches the right hand side of the contact pad 306 can be sufficiently reduced. Therefore, even if the light that propagates from the left hand side manages to reach field enhanced regions along the edge 316(c) (or to the edges 316 (b) and 316(d) closer to the right hand side of the contact pad 306), the intensity of the light is attenuated to levels that do not cause appreciable physical damage to the photoconductive material. Similar principles are applicable to the light that is delivered to the photoconductive switch 302 from the right hand side through fiber optic bundle 310. The light delivered to the second face 314 (not shown in FIG. 3(a)) enters the photoconductive material 304, and then expands and attenuates as it propagates through the photoconductive material 304 in the direction of the first face 312.

The disclosed embodiments further enable the reduction or elimination of current enhancements due to field enhancements around the remaining edges 316(a) and 316(c) of the switch 302. FIG. 3(b) shows a side view of the exemplary photoconductive switch 302 of FIG. 3(a) in accordance with an exemplary embodiment. In FIG. 3(b) the path of incident radiation that initially enters face 314 from the right hand side is shown by solid lines, while the path of incident light that initially enters the face 312 from the left hand side is shown by dashed lines. The incident light from the left hand side tends to diverge as the beam travels through the photoconductive material 304, and is fully or substantially absorbed by the photoconductive material 304. Therefore, the intensity of light that may reach the field enhancement regions around the edge 316(c) is substantially reduced. While it may appear that the intense light that enters through the first face 312 increases the field at the contact edge (it would, if the voltage remained high when the photoconductive switch 302 is operating in the “on” state), the bulk-switched region in the middle of photoconductive switch 302 collapses the voltage on the switch to maintain a minimal field at the edge locations during the “on” state. This requires that the “on” state switch impedance to be significantly lower than the load impedance presented to the switch. An optics device, e.g., a lens assembly, can be used to control the beam divergence of the incident light to the photoconductive material 304 to have the desired spatial divergence property described above. In the example shown where two incident light beams are directed to the photoconductive material 304 from two opposing faces, two optics devices are used to control the beam divergence of the two incident light beams, respectively.

In one exemplary embodiment, a reduction in light received by a photoconductive switch in the vicinity of enhanced-field regions is accomplished by increasing the size of the photoconductive switch and contact pads. This exemplary embodiment can be illustrated by reference to FIGS. 2(a) and 3(a). Specifically, the length and/or width of the photoconductive material 304 and contact pads 306 in FIG. 3(a) can be increased in comparison with the photoconductive material 204 and contact pads 206 in FIG. 2(a), while keeping the spacing of between individual fibers of the fiber optic arrays 308 and 310 in FIG. 3(a) the same as those between individual fibers of fiber optic arrays 208 and 210 in FIG. 2(a). In one specific example, where SiC is selected to be the photoconductive material in both FIGS. 2(a) and 3(a), the dimensions (i.e., width×length×thickness) of the photoconductive switch 202 in FIG. 2(a) are 1 cm×1 cm×1 mm, the dimensions of the photoconductive switch 302 in FIG. 3(a) are 2 cm×2 cm×1 mm, the dimensions (i.e., width×length) of the contact pads 206 in FIG. 2(a) are 8 mm×8 mm, the dimensions (i.e., width×length) of the contact pads 306 in FIG. 3(a) are 18 mm×18 mm, and each of the fiber optic arrays 208, 210, 308, 310 in FIGS. 2(a) and 3(a) is an array of 9 0.4-mm fibers, with a linear extent of 8 mm. In another exemplary embodiment, the photoconductive switch is 1.2 cm×2 cm×1 mm, with an fiber array with a linear extent of 8 mm.

In some exemplary embodiments, the light receiving area at the edge of each photoconductive switch is reduced by reconfiguring the fiber optic arrays so that individual fibers are more closely packed and/or produce output light with smaller cross-sectional areas. In some exemplary embodiments other techniques for delivering light can be used in addition to, or instead of, using fiber optics. For example, optical components such as lenses, prisms, grating, and the like may be used to couple laser light into the photoconductive switch. Further, while the exemplary configuration of FIGS. 3(a) and 4 depict illumination of the switch from two sides, in some embodiments the photoconductive switch is illuminated from one side. In other exemplary embodiments, the photoconductive switch is illuminated from more than two sides.

The exemplary diagram of FIG. 3(a) shows an exemplary photoconductive switch 302 with a square cross-sectional area. It is, however, understood that photoconductive switches with other cross-sectional areas can be implemented in accordance with the embodiments of the present application.

FIG. 4 illustrates a photoconductive switch 402 with a rectangular plan view in accordance with an exemplary embodiment. photoconductive switch 402 includes a rectangular shaped photoconductive material 404 and contact pads 406, where the center section of the photoconductive switch 402 is illuminated via the fiber optic bundles 408 and 410. One or all of at least the following parameters can be adjusted to improve the life span of the photoconductive switch 402: the length, L, and width, W, of the photoconductive material 404, the length LL and width WW of the contact pads 406, the extent, D, of the fiber optic bundle, the spacing, d, between individual fibers, and the divergence angle, θ. By adjusting these parameters, life span of the photoconductive switch 402 can be improved by significantly reducing the light intensity at the field enhancement regions 416(a) through 416(d) of photoconductive switch 402, while, at the same time, achieving suitable light intensity at the center portion of the photoconductive switch. The type/composition of photoconductive material 404 and the wavelength of the light should also be considered when adjusting the above parameters since it affects the absorption of light as it propagates through the photoconductive material 404. By adjusting the above parameters, the intensity of light that is incident on, or otherwise reaches, the field-enhanced regions is eliminated or substantially reduced to maintain the current density in those regions within acceptable levels and to thereby delay the onset of physical damage to photoconductive material in those field-enhanced regions. Note that in connection with the exemplary diagrams of FIGS. 3(a) and 4, proper operation of the photoconductive switch is still maintained since the central region of each switch 302 and 402 is still substantially uniformly illuminated. The central regions of the photoconductive switches 302 and 402 carry the bulk of the current that is needed to operate the switches in an “on” state, albeit at lower current densities than the configuration of FIG. 2(a).

As noted above, by controlling the illumination of field enhanced regions, the life span of a photoconductive switch can be extended. Additionally, some or all of the extended life span of the photoconductive switch can be traded for obtaining the capability to hold higher voltage values. That is, compared to the existing photoconductive switches, the photoconductive switches that are implemented in accordance with the disclosed embodiments can be operate for a longer life span and/or hold higher (e.g., up to 2×) voltages.

FIG. 5 illustrates a set of operations 500 that can be carried out for operating a photoconductive switch in accordance with an exemplary embodiment. At 502, a voltage is supplied to the photoconductive switch. At 504, a first incident radiation is delivered to only a section of a first face of a photoconductive material of the photoconductive switch. The photoconductive material includes the first face and a second face, and the photoconductive material is positioned between a first and a second contact and configured to enable establishment of an electric field across the photoconductive material. Further, such an electric field includes enhancement regions around the periphery of the first and the second contacts. Additionally, the photoconductive material is dimensioned relative to the first and the second contacts such that upon delivering the first incident radiation, the first incident radiation propagates through the photoconductive material toward the second face and reaches one or more regions of electric field enhancement with substantially reduced intensity.

The foregoing description of embodiments has been presented for purposes of illustration and description. The foregoing description is not intended to be exhaustive or to limit embodiments of the present invention to the precise form disclosed, and modifications and variations are possible in light of the above teachings or may be acquired from practice of various embodiments. The embodiments discussed herein were chosen and described in order to explain the principles and the nature of various embodiments and its practical application to enable one skilled in the art to utilize the present invention in various embodiments and with various modifications as are suited to the particular use contemplated. For example, the exemplary embodiments have been described in the context of proton beams. It is, however, understood that the disclosed principals can be applied to other charged particle beams and/or applications other than accelerators. Moreover, the generation of extremely short charged particle pulses that are carried out in accordance with certain embodiments may be used in a variety of applications that range from radiation for cancer treatment, probes for spherical nuclear material detection or plasma compression, or in acceleration experiments. The features of the embodiments described herein may be combined in all possible combinations of methods, apparatus, modules, systems, and computer program products.

What is claimed is:

1. A photoconductive switch, comprising:
a photoconductive material structured to comprise a first face and a second face; and
a first contact and a second contact placed on two opposing surfaces of the photoconductive material to enable establishment of an electric field across the photoconductive material, including electric field enhancement regions around the periphery of the first and the second contacts;
wherein the photoconductive material is dimensioned relative to the first and the second contacts to allow a first incident radiation that enters the photoconductive material through the first face to propagate through the photoconductive material toward the second face and reach one or more electric field enhancement regions with substantially reduced intensity.

2. The photoconductive switch of claim 1, wherein the photoconductive material is dimensioned relative to the first and the second contacts to allow a second incident radiation that enters the photoconductive material through the second face to propagate through the photoconductive material toward the first face and reach one or more additional regions of electric field enhancement with substantially reduced intensity.

3. The photoconductive switch of claim 1, wherein the photoconductive material comprises silicon carbide (SiC).

4. The photoconductive switch of claim 1, wherein the first incident radiation is light produced by a laser.

5. A system comprising the photoconductive switch of claim 1, wherein:
the system further comprises a first source configured to produce the first incident radiation; and
a spatial extent and divergence of the first incident radiation produced by the first source is selected to sustainably avoid illumination of one or more further regions of electric field enhancement, or to allow the first incident radiation that enters the photoconductive material through the first face to propagate through the photoconductive material toward the second face and reach the one or more further regions of electric field enhancement with substantially reduced intensity.

6. The system of claim 5, further comprising a fiber optic bundle configured to deliver the first incident radiation to the first face of the photoconductive material.

7. The system of claim 5, further comprising one or more optical components configured to deliver the first incident radiation to the first face of the photoconductive material.

8. The system of claim 7, wherein the one or more optical components comprise one or more of: a lens, a prism, and a grating.

9. The system of claim 5, further comprising a voltage source configured to supply one or more voltage values to the first and the second contacts.

10. A system comprising the photoconductive switch of claim 2, wherein the system further comprises a first source configured to produce the first incident radiation and a second source configured to produce the second incident radiation;
a spatial extent and divergence of the first incident radiation produced by the first source is selected to sustainably avoid illumination of one or more further regions of electric field enhancement, or to allow the first incident radiation that enters the photoconductive material through the first face to propagate through the photoconductive material toward the second face and reach the one or more further regions of electric field enhancement with substantially reduced intensity; and
a spatial extent and divergence of the second incident radiation produced by the second source is selected to sustainably avoid illumination of the one or more further regions of electric field enhancement, or to allow the second incident radiation that enters the photoconductive material through the second face to propagate through the photoconductive material toward the first face and reach the one or more further regions of electric field enhancement with substantially reduced intensity.

11. The photoconductive switch of claim 1 configured to operate with a Blumlein of a dielectric wall accelerator.

12. The photoconductive switch of claim 1, wherein the photoconductive material is dimensioned to allow a central region of the photoconductive material be substantially uniformly illuminated by radiation entering the photoconductive material from the first face or radiation entering the photoconductive material from the second face.

13. The photoconductive switch of claim 1, wherein the photoconductive material and the first and the second contacts are dimensioned based on at least one of:
a length of the photoconductive material relative to a length of the first and the second contacts along a direction of radiation propagation through the photoconductive material;
a length of the photoconductive material and a length of the first and the second contacts relative to an amount of radiation absorption along a direction of radiation propagation through the photoconductive material;
a width of the photoconductive material, transverse to a direction of radiation propagation through the photoconductive material, relative to a width of a section of the first face or the second face that receives incident radiation;
a width of the first and the second contacts, transverse to a direction of radiation propagation through the photoconductive material, relative to a width of a section of the first face or the second face that receives incident radiation;
a divergence angle or angles of radiation that enters the photoconductive material through the first face or the second face and propagates through the photoconductive material towards an opposite face;
a composition of the photoconductive material;
a spacing between individual fibers of a fiber optic bundle configured to deliver the first radiation to the first face of the photoconductive material; or
a spacing between individual fibers of a fiber optic bundle configured to deliver a second radiation to the second face of the photoconductive material.

14. The photoconductive switch of claim 1, comprising:
a plurality of optical fibers positioned relative to the photoconductive material to direct light as the first incident radiation into the first face to enter the photoconductive material at locations towards the center portion of photoconductive material while being away from one or more electric field enhancement regions around the periphery of the first and the second contacts,
wherein the first incident radiation has sufficient power to cause the photoconductive material to become photoconductive to provide electrical conductivity in the photoconductive material between the first and second contacts.

15. The photoconductive switch of claim 14, comprising:
a plurality of second optical fibers positioned relative to the photoconductive material to direct light as a second incident radiation into the second face to enter the photoconductive material at locations towards the center portion of photoconductive material while being away from one or more electric field enhancement regions around the periphery of the first and the second contacts,
wherein the first and second incident radiation have sufficient power to cause the photoconductive material to become photoconductive to provide electrical conductivity in the photoconductive material between the first and second contacts.

16. The photoconductive switch of claim 1, comprising:
an optics module placed in an optical path of the first incident radiation to the first face of the photoconductive material to control a beam divergence of the first incident radiation inside the photoconductive material so that the first incident radiation diverges inside the photoconductive material to substantially reduce an optical intensity of the first incident radiation when reaching to an opposite face of the photoconductive material.

17. A method for operating a photoconductive switch, comprising:
supplying a voltage value to the photoconductive switch; and
delivering a first incident radiation to only a section of a first face of a photoconductive material of the photoconductive switch, the photoconductive material comprising the first face and a second face, the photoconductive material positioned between a first and a second contact configured to enable establishment of an electric field across the photoconductive material, the electric field including enhancement regions around the periphery of the first and the second contacts,
wherein the photoconductive material is dimensioned relative to the first and the second contacts such that upon delivering the first incident radiation, the first incident radiation propagates through the photoconductive material toward the second face and reaches one or more regions of electric field enhancement with substantially reduced intensity.

18. The method of claim 17, further comprising:
delivering a second incident radiation to only a section of the second face, wherein
the photoconductive material is dimensioned relative to the first and the second contacts such that upon delivering the second incident radiation, the second incident radiation propagates through the photoconductive material toward the first face and reaches one or more additional regions of electric field enhancement with substantially reduced intensity.

19. The method of claim 17, wherein the first incident radiation is light produced by a laser.

20. The method of claim 17, wherein the delivering comprises delivering the first incident radiation to the first face using a fiber optic bundle.

21. The method of claim 17, wherein the first incident radiation is delivered to the first face using one or more optical components.

22. The method of claim 21, wherein the one or more optical components comprise one or more of: a lens, a prism, and a grating.

23. The method of claim 17, wherein upon delivery of the first incident radiation, a current flow is established between the first and the second contacts.

24. The method of claim 17, further comprising substantially eliminating a current flow between the two contacts by reducing or halting one or both of:
supply of the voltage to the photoconductive switch, and
delivery of the first incident radiation.

25. The method of claim 17, wherein delivery of the first incident radiation comprises controlling a spatial extent and divergence angle of the first incident radiation such that illumination of one or more further regions of electric field enhancement is avoided, or such that the first incident radiation that enters the photoconductive material through the first face propagates through the photoconductive material toward the second face and reaches the one or more further regions of electric field enhancement with substantially reduced intensity.

26. The method of claim 18, wherein delivery of the second incident radiation comprises controlling a spatial extent and divergence angle of the second incident radiation such that illumination of one or more further regions of electric field enhancement is avoided, or such that the second incident radiation that enters the photoconductive material through the second face propagates through the photoconductive material toward the first face and reaches the one or more further regions of electric field enhancement with substantially reduced intensity.
